(19) United States
(12) Patent Application Publication
(10) Pub. No.: US 2015/0041750 A1
(43) Pub. Date: Feb. 12, 2015

(54) Resistive Memory Device and Method for Fabricating the Same

(71) Applicant: Peking University, Beijing (CN)

(72) Inventors: Yimao Cai, Beijing (CN); Jun Mao, Beijing (CN); Huiwei Wu, Beijing (CN)

(21) Appl. No.: 14/378,014

(22) PCT Filed: Oct. 11, 2012
(86) PCT No.: PCT/CN2012/082793

§ 371 Date: Aug. 11, 2014

(30) Foreign Application Priority Data
Sep. 25, 2012 (CN) 201210359880.2

(51) Int. Cl. H01L 45/00; H01L 27/24

(52) U.S. Cl. CPC H01L 45/145; H01L 45/146; H01L 45/1608; H01L 45/1675; H01L 27/24
USPC 257/4; 438/382

(57) ABSTRACT

An embodiment of the present invention provides a resistive memory device and a method for fabricating the same. The resistive memory device includes a substrate and a plurality of memory cells spaced with each other over the substrate, each memory cell including a lower electrode, a resistive layer and an upper electrode, wherein the lower electrode is disposed over the substrate, the resistive layer is disposed over the lower electrode and the upper electrode is disposed over the resistive layer, and the resistive layer includes a resistive material portion and at least one doped resistive portion doped with an element for adjusting a resistance state. In the resistive memory device and the method for fabricating the same according to the present invention, since the resistive layer is not formed of single resistive material, during a set operation of the resistive memory device, a plurality of stable resistance states are produced according to various applied voltages, so that a storage density of the resistive memory device is increased without increasing a volume of the resistive memory device.

### FIELD OF THE INVENTION

The invention relates to a field of semiconductor devices, in particular, to a resistive memory device and a method for fabricating the same, and more particular, to a multi-value resistive memory device and a method for fabricating the same.

### BACKGROUND OF THE INVENTION

A memory device is an indispensable part for various electronic devices and is widely used in many portable devices, such as cell phones, notebooks and PDAs. Generally, the memory device uses a high level and a low level to represent 1 and 0 respectively so as to store information.

Currently, some of the memory devices are floating-gate flash memory devices which use a polysilicon gate combined with other material (such as Phosphorus and Boron) as a floating-gate and a control gate. However, with the rapid development of the flash memory device, the size of the flash memory device has greatly reduced. Specially, after entering the technical node of 45 nm, the space between flash memory cells reduces and thus the interference between flash memory cells becomes larger, resulting in that the reliability of the flash memory device has been affected. Meanwhile, the flash memory device is difficult to realize a multi-value storage due to the intrinsic physical property of the flash memory device.

In comparison, the resistive memory device has been widely used due to the properties such as high stability, high reliability, a simple structure and compatibility with the COMS process. The resistive memory device is a novel memory device which can store data by applying voltages with different polarities and levels to change the resistance of the resistive material. In term of the structure, each memory cell includes an upper electrode, a resistive material and a lower electrode.

In order to meet the requirements for the storage capacity, people on one hand make the memory cells smaller by means of new structures and new processes so as to improve the storage density, on the other hand, a memory cell which has a multi-value other than the high level and the low level is also required. Thus, more stable intermediate states may be used for information storage, so that the multi-value storage is implemented and the storage density is improved.

### SUMMARY OF THE INVENTION

In view of the above prior art that the multi-value is difficult to be implemented, a resistive memory device and a method for fabricating the same are provided by an embodiment of the present invention.

In one aspect, an embodiment of the present invention provides a resistive memory device, the resistive memory device includes a substrate and a plurality of memory cells spaced with each other on the substrate, each memory cell including a lower electrode, a resistive layer and an upper electrode, wherein the lower electrode is disposed over the substrate, the resistive layer is disposed over the lower electrode and the upper electrode is disposed over the resistive layer, and the resistive layer includes a resistive material portion and at least one doped resistive portion doped with an element for adjusting a resistance state.

In another aspect, an embodiment of the present invention provides a method for fabricating a resistive memory device, wherein the method includes the following steps: step 1, forming a plurality of lower electrodes on a semiconductor substrate; step 2, growing a resistive layer over the plurality of lower electrodes, and forming an upper electrode over the resistive layer; step 3, removing the resistive layer and the upper electrode between two adjacent lower electrodes by using an etching process, so as to form a plurality of memory cells; step 4, performing an ion implantation to the resistive layer to dope an element for adjusting a resistance state into the resistive layer, so that the resistive layer include a resistive material portion and at least one doped resistive portion doped with the element for adjusting the resistance state.

Compared with the prior art, in the resistive memory device provided by the embodiment of the present invention, the resistive layer includes a resistive material portion and at least one doped resistive portion. Because the doped resistive portion is doped with the element for adjusting the resistance state, a resistance state of the resistive material portion is different from that of the doped resistive portion, and a voltage causing resistance change of the resistive material portion is different from that of the doped resistive portion. Hence, during a set operation of the resistive memory device, with the change of the applied voltage, a plurality of stable resistance states of the resistive memory device may be obtained, and consequently various stable storage states of the resistive memory device may be achieved. Therefore, the resistive memory device is not limited to the two stable storage states 0 and 1, and thus the storage density is increased.

Moreover, according to the method for fabricating the resistive memory device of the embodiment of the present invention, a volume of the resistive layer is not increased. Thus, the storage density of the resistive memory device can be improved without changing the volume of the resistive layer.

### BRIEF DESCRIPTION OF THE DRAWINGS

In order to describe an embodiment of the present invention or the technical solution in the prior art more clearly, descriptions of the drawings used in the embodiment are briefly provided. Apparently, drawings as below are a part of the embodiment of the present invention and those skilled in the art can appreciate many other implementations without any inventive work.

FIG. 1 shows a structure of a multi-value resistive memory device according to an embodiment of the present invention;

FIGS. 2, 3, 4, 5 and 6 show flow diagrams for fabricating a multi-value resistive memory device according to an embodiment of the present invention.

### DETAILED DESCRIPTION OF THE EMBODIMENTS

Hereinafter, the technical solution of the present invention is described in more details with reference to the accompany drawings in the embodiment. Apparently, the described embodiment is only a part of the present invention and is not intended to limit the invention. Embodiments which can be obtained by those skilled in the art without any inventive work also fall into the scope of the present invention.

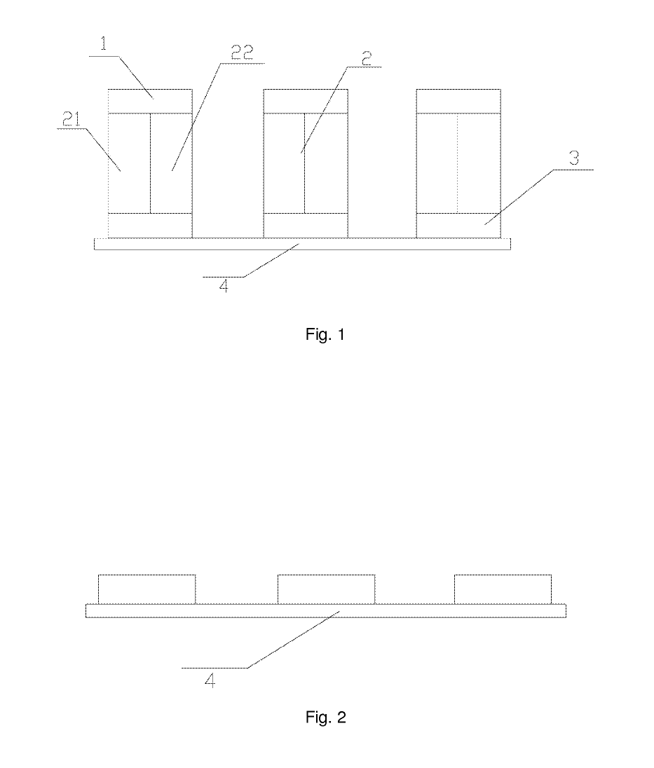

Referring to FIG. 1, FIG. 1 shows a structure of a multi-value resistive memory device according to an embodiment of the present invention. As shown in FIG. 1, the multi-value resistive memory device according to the embodiment of the present invention includes a substrate 4 and a plurality of memory cells spaced with each other on the substrate 4. Each memory cell includes a lower electrode 3, a resistive layer 2 and an upper electrode 1, wherein the lower electrode is disposed over the substrate, the resistive layer is disposed over the lower electrode and the upper electrode is disposed over the resistive layer. The resistive layer includes a resistive material portion 21 and at least one doped resistive portion 22 doped with an element for adjusting a resistance state.

It is noted that, although only one doped resistive portion 22 is shown in FIG. 1, FIG. 1 is merely an example and the number of the doped resistive portions may be two or more.

Among them, the resistive material portion may be formed of any material suitable for being used as the resistive material, which may be already known or would be appeared in future. In a preferable embodiment of the present invention, the resistive material portion may be formed of one of silicon oxide SiOx, germanium oxide GeOx, titanium oxide TaOx and hafnium oxide HfOx.

Also, the element for adjusting the resistance state may be any material suitable for being doped into the resistive material, which may be already known or would be appeared in future. In a preferable embodiment of the present invention, the element doped for adjusting the resistance state may be N element, O element, P element, B element or S element. By doping the above-mentioned element for adjusting the resistance state into the metal oxide material, the matching of chemical bonding on one hand may be ensured, and the crystalline quality on the other hand may also be ensured by a displacement doping.

In addition, in the resistive memory device according to the embodiment of the present invention, the upper electrode may be formed to have a proper thickness so as to be a protection of the underlying structure. In a preferable embodiment of the present invention, a thickness of the upper electrode may be larger than or equal to 50 nm.

In the multi-value resistive memory device according to the embodiment of the present invention as shown in FIG. 1, the resistance state of the resistive material may be changed so as to store data by a change of voltage. For example, in the case that the resistive material is SiO and the element doped for changing the resistance state is N element, the resistive layer includes a resistive material portion of SiO and a doped resistive portion of SiON. Assuming that a high resistance state and a low resistance state of SiO are Rhigh1 and Rlow1 respectively, a high resistance state and a low resistance state of SiON are Rhigh2 and Rlow2 respectively, and a voltage causing resistance change of SiO is Vset1 and a voltage causing resistance change of SiON is Vset2, wherein Vset1>Vset2 (the higher a metallic bond energy is, the higher a voltage for broking a chemical structure is; the bond energy between Si element and O element is higher than that between Si element and N element). In an initial state, the two portions of the resistive layer are both in a low resistance state Rlow1 and Rlow2, and thus the resistance state of each memory cell is equivalent to a result of Rlow1 and Rlow2 in parallel. In a set operation of the resistive memory device, a positive voltage V is applied. In the case that Vset2<V<Vset1, a resistance change occurs in the doped resistive portion of SiON and thus the resistance state thereof changes from Rlow2 to Rhigh2, while the resistive material portion of SiO keeps in the low resistance state, i.e. Rlow1. Thus, the resistance state of each memory cell is equivalent to a result of the low resistance state Rlow1 and the high resistance state Rhigh2 in parallel. As the set voltage increases, in the case that V>Vset1, a resistance change occurs in the resistive material portion of SiO and thus the resistance state thereof changes from the low resistance state Rlow1 to the high resistance state Rhigh1, and at this time the resistance state of each memory cell is equivalent to a result of the high resistance states Rhigh1 and Rhigh2 in parallel. Therefore, compared with the prior art, each memory cell in the multi-value resistive memory device according to the embodiment of the present invention can effectively store three individual states, and thus the storage density of the multi-value resistive memory device is effectively improved.

The above descriptions are merely examples and the present invention is not limited thereto. For example, the number of the doped resistive portions may be two or more. In another embodiment of the present invention, for example, in the case that the resistive layer is formed of SiO and the element for adjusting the resistance state is N element, the resistive layer may include a resistive material portion and two doped resistive portions, wherein the two doped resistive portions are located at both sides of the resistive material portion, respectively. One doped resistive portion at one side of the resistive material portion has a lower doping concentration of the doped N element (for example, the concentration of the doped N element is close to that of O element in the resistive material) and thus a resistive material of SiON is formed. The other doped resistive portion at the other side of the resistive material portion has a higher doping concentration of the doped N element (for example, the concentration of the doped N element is much higher than that of O element in the resistive material) and thus a resistive material of SiN is formed. In this way, the multi-value resistive memory device is equivalent to three resistive memory devices connected in parallel and has more numbers of stable resistance states for storage of more states.

FIGS. 2, 3, 4, 5 and 6 show a flow for fabricating a multi-value resistive memory device according to an embodiment of the present invention. The flow includes the following steps.

Step 1: a plurality of lower electrodes 3 are formed over a semiconductor substrate 4.

In the embodiment as shown in FIG. 2, the lower electrodes 3 may be formed over a silicon substrate 4. For example, the lower electrodes 3 may be formed over the substrate by using a metal deposition process and an etch process.

For example, the lower electrodes may be formed of any one material of platinum, tungsten, nickel, aluminium, palladium and gold.

Step 2: a resistive layer 2 is grown over the plurality of lower electrodes, and an upper electrode 1 is formed over the resistive layer 2.

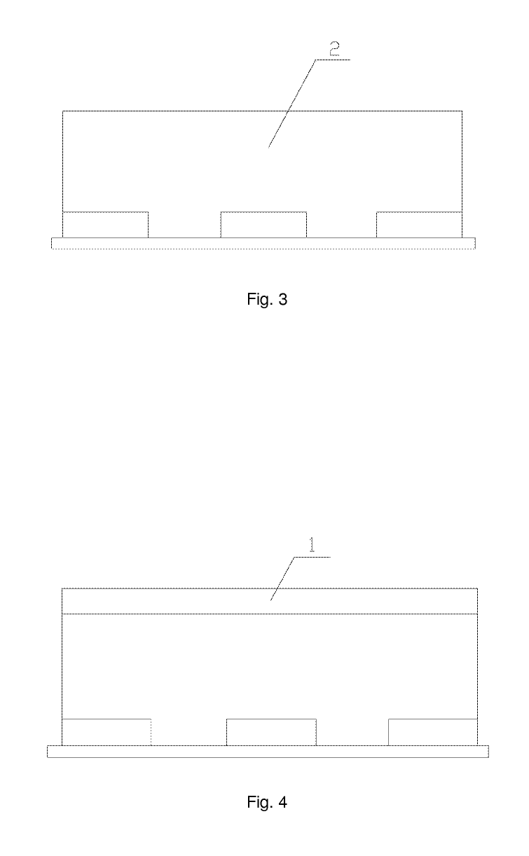

As shown in FIG. 3, the resistive layer 2 may be grown over the lower electrodes 3 by using a deposition process.

Among them, the resistive material may be any material suitable for being used as the resistive material, which is already known or would be used in future. In a preferable embodiment of the present invention, the resistive material may be metal oxide material such as one of silicon oxide SiOx, germanium oxide GeOx, titanium oxide TaOx and hafnium oxide HfOx.

Then, as the embodiment shown in FIG. 4, an upper electrode 1 may be formed over the resistive material. For example, the upper electrode may be formed over the resistive material by using a metal deposition process.

For example, the upper electrode may be formed of any one material of platinum, tungsten, nickel, aluminium, palladium and gold.

Step 3: a plurality of memory cells are formed by removing the upper electrode and the resistive layer between two adjacent lower electrodes using an etching process.

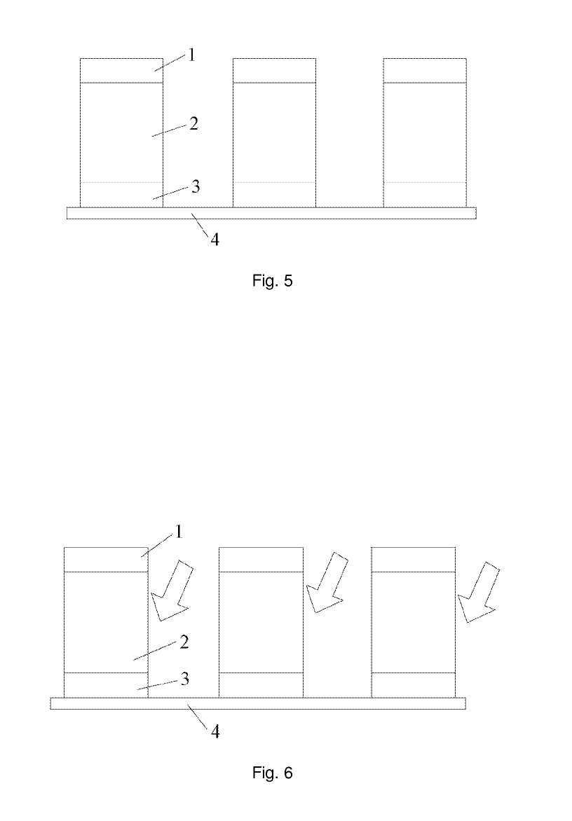

As shown in FIG. 5, the respective memory cells are formed by removing the upper electrode and resistive layer between two adjacent lower electrodes over the silicon substrate using an etching process.

Step 4: an ion implantation process is performed to the resistive layer so that an element for adjusting a resistance state is doped into the resistive layer. Thus, as shown in FIG. 1, the resistive layer 2 after the ion implantation includes a resistive material portion 21 and at least one doped resistive portion 22 doped with the element for adjusting the resistance state.

Among them, the doped element for adjusting the resistance state may be any material suitable for adjusting the resistance state, which is already known or would be used in future. In a preferable embodiment of the present invention, for example, the doped element for adjusting the resistance state may be N element, O element, P element, B element or S element. By doping the element for adjusting the resistance state into the resistive material, the matching of chemical bonding is maintained and moreover, the crystalline quality is ensured by a displacement doping.

As shown in FIG. 6, the ion implantation may be performed with a certain angle. In an embodiment of the present invention, the implantation angle of the element for adjusting the resistance state may be adjusted based on an interval between every two adjacent individual memory cells, as long as the element for adjusting the resistance state is only implanted at one side. In a preferable embodiment of the present invention, the angle ranges from 20°-60°.

In addition, in the above embodiment of the present invention, the implantation dose of the element for adjusting the resistance state may be determined based on a proportion of the element to be formed in the doped resistive material. Moreover, the implantation energy of the element may be determined based on a thickness of the resistive material. In a preferable embodiment, the energy may be 10-40 KeV.

Compared with the prior art, in the resistive memory device provided by the method according to the embodiment of the present invention, the resistive layer includes a resistive material portion and at least one doped resistive portion. Because the doped resistive portion is implanted with the element for adjusting the resistance state, the resistance state of the resistive material portion is different from that of the doped resistive portion, and the voltage causing resistance change of the resistive material portion is different from that of the doped resistive portion. Hence, during the set operation of the resistive memory device, with the change of the applied voltage, a plurality of stable resistance states of the resistive memory device may be obtained, and consequently various stable storage states of the resistive memory device may be achieved. In this way, the resistive memory device is not limited to the two stable storage states 0 and 1, and thus the storage density is increased.

Moreover, in the resistive memory device and the method for fabricating the same according to the embodiment of the present invention, the volume of the resistive layer is not changed. Thus, the storage density is improved and the multi storage of the memory cell is realized without changing the volume of the resistive memory device.

What is claimed is:

1. A resistive memory device, wherein the resistive memory device comprises a substrate (4) and a plurality of memory cells spaced with each other on the substrate, each memory cell comprising a lower electrode (3), a resistive layer (2) and an upper electrode (1), wherein the lower electrode is disposed over the substrate, the resistive layer is disposed over the lower electrode and the upper electrode is disposed over the resistive layer, and the resistive layer comprises a resistive material portion (21) and at least one doped resistive portion (22) doped with an element for adjusting a resistance state.

2. The resistive memory device of claim 1, wherein the resistive material portion is formed of one of silicon oxide SiOx, germanium oxide GeOx, titanium oxide TaOx and hafnium oxide HfOx.

3. The resistive memory device of claim 1, wherein the element for adjusting the resistance state is N element, O element, P element, B element or S element.

4. The resistive memory device of claim 1, wherein a thickness of the upper electrode is larger than or equal to 50 nm.

5. A method for fabricating a resistive memory device, wherein the method comprises the following steps:
Step 1: forming a plurality of lower electrodes (3) on a semiconductor substrate (4);
Step 2: growing a resistive layer (2) over the plurality of lower electrodes, and forming an upper electrode (1) over the resistive layer;
Step 3: removing the resistive layer and the upper electrode between two adjacent lower electrodes by using an etching process, so as to form a plurality of memory cells;
Step 4: performing an ion implantation to the resistive layer to dope an element for adjusting a resistance state into the resistive layer, so that the resistive layer comprises a resistive material portion and at least one doped resistive portion doped with the element for adjusting the resistance state.

6. The method for fabricating the resistive memory device of claim 5, wherein the resistive material portion is formed by using one of silicon oxide SiOx, germanium oxide GeOx, titanium oxide TaOx and hafnium oxide HfOx.

7. The method for fabricating the resistive memory device of claim 5, wherein the element for adjusting the resistance state is N element, O element, P element, B element or S element.

8. The method for fabricating the resistive memory device of claim 5, wherein the ion implantation is performed with an angle ranging from 20°-60°.

9. The method for fabricating the resistive memory device of claim 5, wherein the ion implantation is performed with an energy ranging from 10-40 keV.
